(19) United States
(12) Patent Application Publication
(10) Pub. No.: US 2004/0234085 A1
(43) Pub. Date: Nov. 25, 2004

(54) Portable audio amplifying apparatus for handheld multimedia devices and uses thereof

(76) Inventor: Timothy Jon Lennox, New York, NY (US)

Correspondence Address: Albert Wai-Kit Chan, Law Offices of Albert Wai-Kit Chan LLC, World Plaza, Suite 604, 141-07 20th Avenue, Whitestone, NY, 11357, US

(21) Appl. No.: 10/825,738

(22) Filed: Apr. 16, 2004

(51) Int. Cl. G10H 1/00; H03F 21/00

(52) U.S. Cl. 381/118; 381/120

(57) ABSTRACT

The invention provides a portable audio amplifying apparatus for an MP3 player, particularly various IPOD™ models, and any other portable handheld multimedia device, which comprises a receptacle, a connecting means, an amplifier means, at least one audio speakers and a power source means. The receptacle is made up of a door assembly and a lock plate assembly operatively linked to accommodate all existing MP3 players or portable handheld multimedia devices that are smaller than the original IPOD™ player while allowing easy access to the control units during playback. Sliding the multimedia device into the receptacle and closing the door locks the device into place to ensure extremely secure compartment. The connecting means is made up of a finger grasp, an input plug, a spring mechanism and a cable connector. Furthermore, the unique design of the finger grasp allows easy movements of large fingers within limited space of the receptacle.

Throughout this application, various publications are referenced. Disclosures of these publications in their entireties are hereby incorporated by reference into this application in order to more fully describe the state of the art to which this invention pertains.

### BACKGROUND OF THE INVENTION

This invention relates to a portable audio amplifying apparatus for portable handheld multimedia devices.

The original boom box using a cassette player provided an affordable and portable means to listen to music. The problem with the original boom box is that the more stable, solid-state components or integrated circuits that make up the amplifier and speaker portions of a boom box survive the more rapid demise of the cassette player with many moving parts, which wear too quickly. Replacing the cassette player with a more durable source of music, such as a CD player, did not eliminate entirely this waste of good components.

What was needed was the ability to replace the “source” of music containing moving parts, whether that be a CD or cassette player, in the same way we do in a “component” home stereo. That way, one can continue to use the amplifier portion while it lasts and would not have to worry about replacing the entire CD or cassette player whenever the components containing the moving parts fail.

Recent developments in consumer electronics have introduced portable handheld multimedia devices such as MP3 players, which enable a user to download audio files from an internet site and store them in an MP3 (MPEG-1 audio layer 3) format for subsequent organizing, transmitting, manipulating, reviewing and selective listening. MP3 players (such as the IPOD™ player manufactured by Apple Computer, Inc. of Cupertino, Calif. in 2001) have revolutionized many people's music-listening experience and music fans now loathe using a cassette or CD player.

The problem with these portable handheld multimedia devices is that they are devoid of any means of amplification. If an owner of an IPOD™, for instance, desires portable amplified music as experienced through a cassette tape or CD player, he or she will have to invest in a second player, which is often cost prohibitive.

The only reasonable alternative, therefore, is a portable “dockable” boom box that is compatible with most of existing multimedia devices and true to the sense of a portable amplifier. This boom box will also solve the problem of the source of music wearing out long before the more stable and solid components or integrated circuits, which make up the amplifier and speaker portions. To restate, in the evolution of the portable handheld multimedia devices, combination of them with a convenient and mobile amplification vehicle or “boom box” is a very logical step.

Up until now, however, there is nothing on the market which directly addresses this potential need of a truly portable amplifying device which would accommodate most of the existing MP3 players, such as an IPOD™, IPOD™ 2.0, IPOD™ 3.0 and IPOD™ mini, or other portable handheld multimedia devices on the market.

The InMotion System introduced by Altec Lansing is known to be the first attempt to create a portable amplifier for the IPOD™. The problem with the InMotion System is that, while the system may be compact and portable, it cannot be easily moved around once the unit is set up and the multimedia device is playing. Attempting to do so is likely to result in the IPOD™ falling out of the system and even possibly being damaged in the process.

Furthermore, the InMotion System is only compatible with older MP3 players such as the original IPOD™ and not with newer and smaller models such as an IPOD™ mini. To accommodate smaller MP3 players, the system will need extra hardware (assuming this can be achieved) and consumers will have to purchase it at additional expenses whether they use such hardware or not.

The innovation in this product comes from its compatibility and portability. This portable amplifying apparatus is compatible with all existing MP3 players and other portable handheld multimedia devices that are smaller than the original IPOD™, and consumers do not have pay for extra hardware. In addition, unlike the InMotion System, this standalone product can be easily moved around while the source of music is playing, which makes this invention true to the sense of a portable amplifier.

### SUMMARY OF THE INVENTION

The invention relates to a portable audio amplifying apparatus for portable handheld multimedia devices. This amplifying apparatus can be considered as six main parts: a receptacle, a connecting means, an amplifier means, at least one speaker 1, a power source means, and a handle 2. As used herein, a power source means includes but is not limited to a plurality of batteries, a rechargeable battery module and an AC power source via a DC adaptor.

The receptacle is made up of a door assembly and a lock plate assembly operatively linked to the receptacle. The receptacle has a narrow space 3 carved in along one side of the wall.

The door assembly is made up of a door 4, a brace 5 and an axle 6. The lock plate assembly is made up of a plate 7, a spring mechanism 8, and a plug connector pad 9 on top of the plate 7. These parts are assembled together with adhesive after molding.

The connecting means is made up of a finger grasp 10, an input plug 11, a spring mechanism 12 and a cable connector 13.

The amplifier means is made up of an input cable and an audio signal sensor.

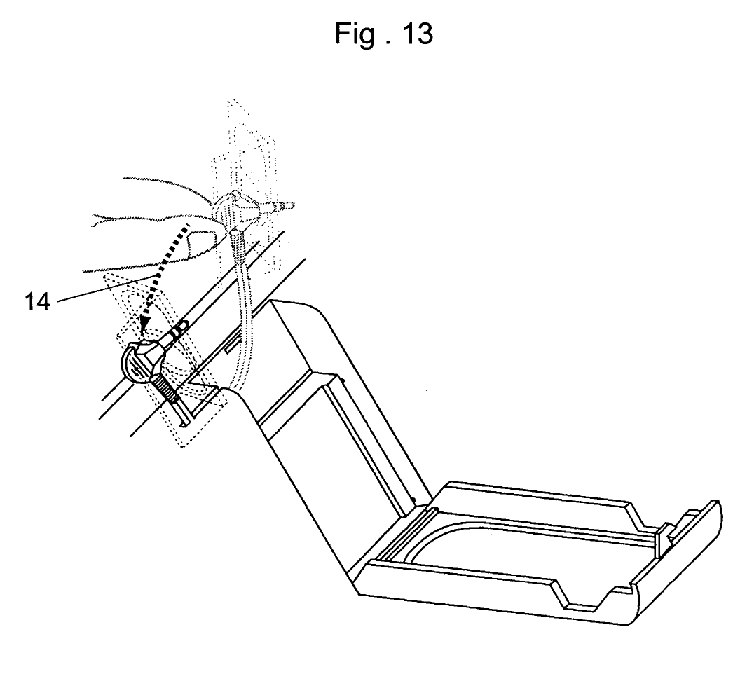

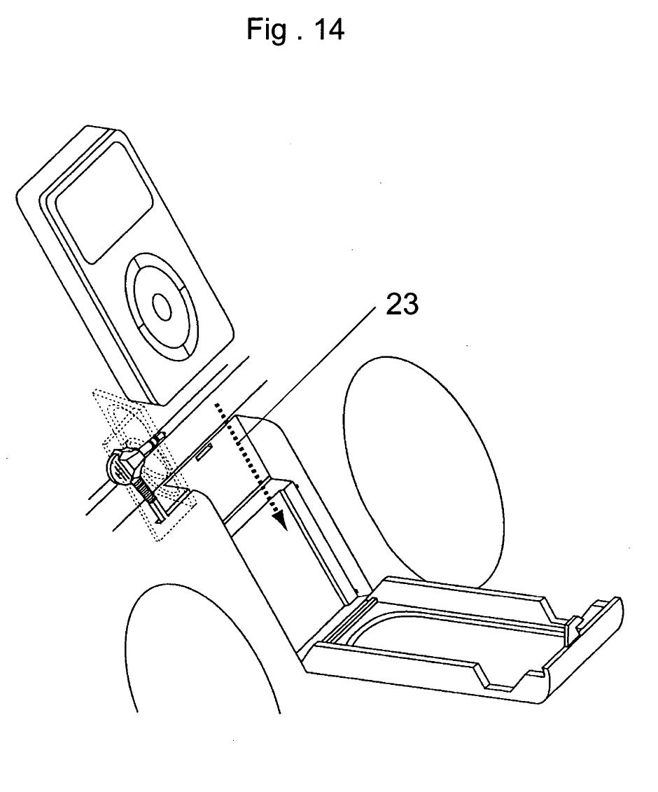

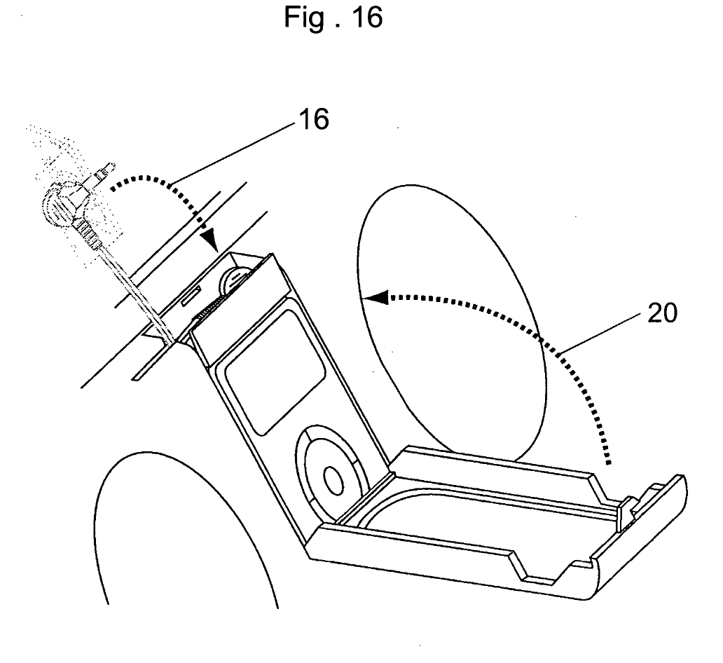

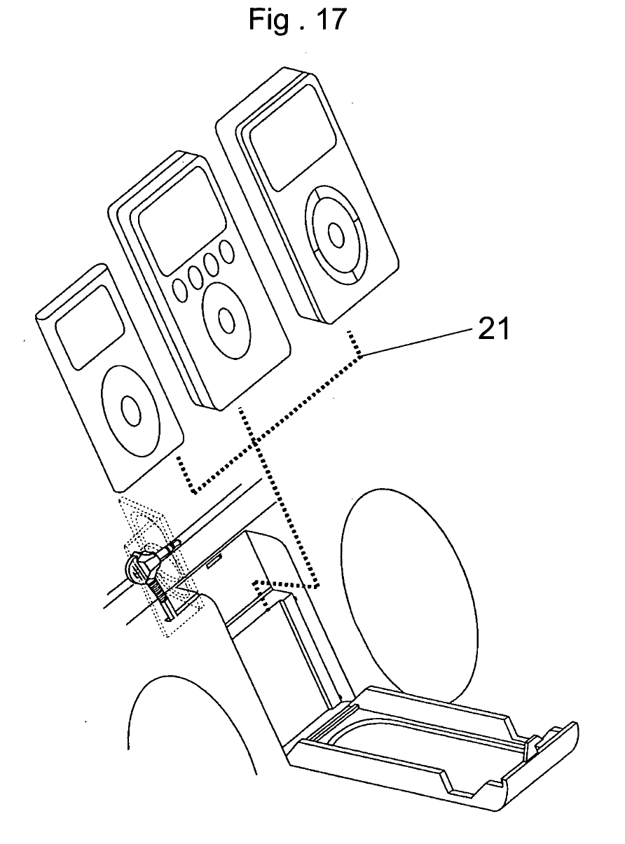

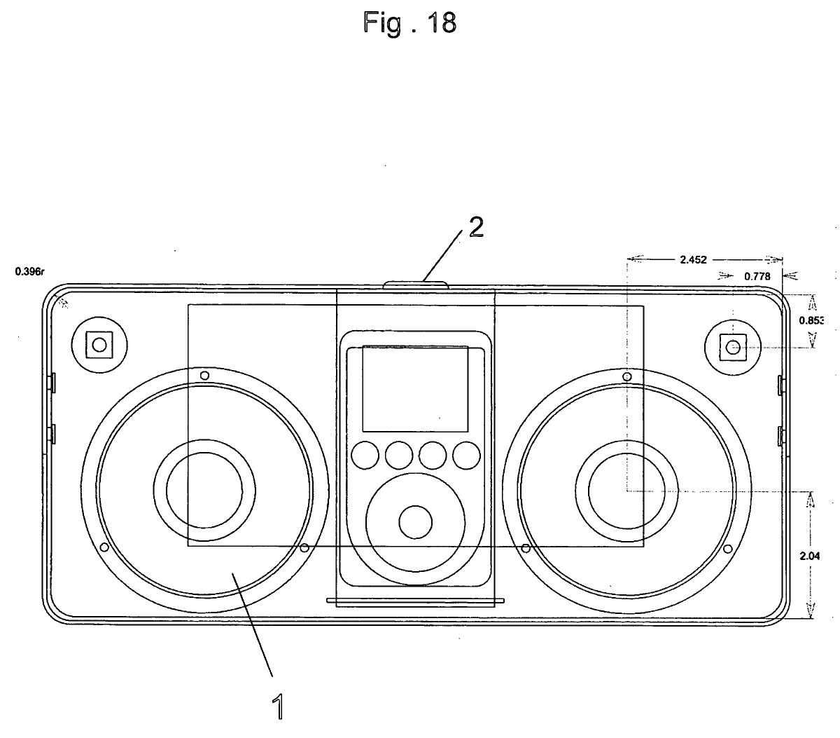

This invention is designed to be used as follows. The door 4 of the receptacle is normally closed, and pressing a button on top of the unit would release the door 4. The input plug 11 that is nestled in the space 3 along the side wall of the receptacle should be pushed aside prior to sliding an IPOD™, an MP3 player or any other portable handheld multimedia device into the receptacle (this is shown as arrow 14 in FIG. 13). Once the device is in place, the input plug 11 should then be inserted into an “audio out” or “headphone” jack of the device through a hole 15 in the plug connector pad 9 on top of the lock plate 7 (this is shown as arrow 16 in FIG. 16) and should be rotated and moved laterally (these are shown as arrows 18 and 19, respectively, in FIG. 15) for a desired tight fit. Once the door 4 of the receptacle is closed (this is shown as arrow 20 in FIG. 16), the lock plate 7 pushes forward the portable handheld multimedia device of various sizes (this is shown as line 21 in FIG. 17) to stabilize the device and to allow easy access to the device's control units, which can be accessed and manipulated through the opening in the door 4. To remove the multimedia device, the button on top should be pressed to release the door 4 open.

### DETAILED DESCRIPTION OF THE FIGURES

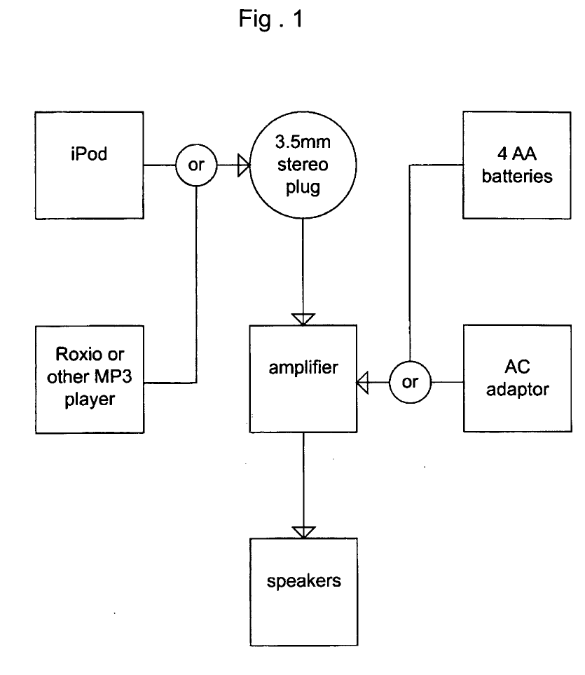

This invention relates to a portable audio amplifying apparatus for portable handheld multimedia devices. The concept of this invention is shown in FIG. 1 to FIG. 18.

The drawings which illustrate specific embodiments of the invention should not be construed as restricting the spirit or scope of the invention in any way:

FIG. 1 is a connectivity flow chart.

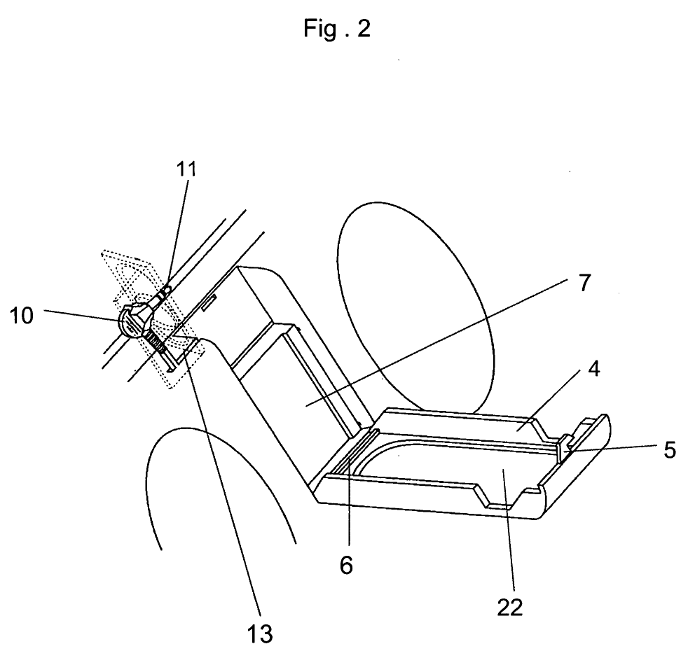

FIG. 2 is a slanted front view of the receptacle.

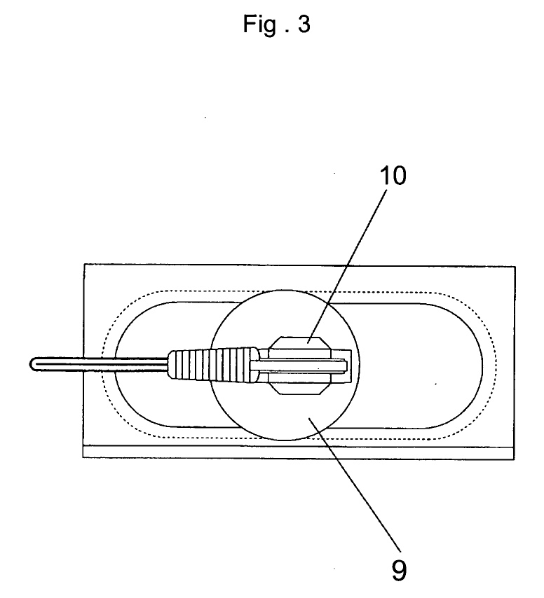

FIG. 3 is a top view of the finger grasp and the input plug nestled in the plug connector pad of the lock plate assembly.

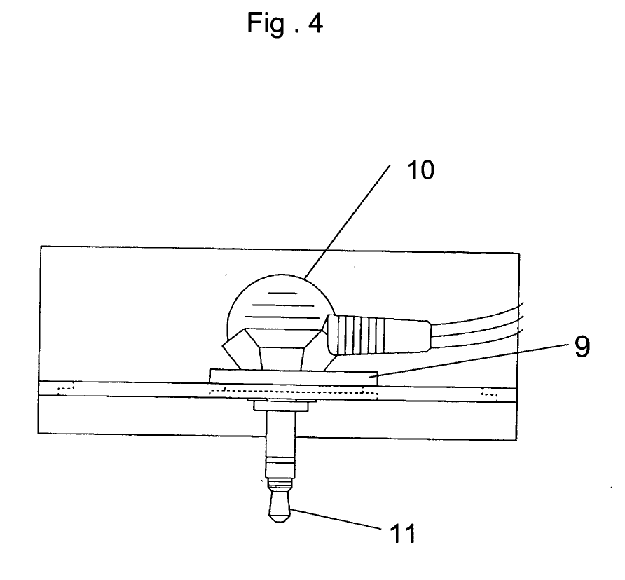

FIG. 4 is a sectional view of the finger grasp and the input plug nestled in the plug connector pad of the lock plate assembly.

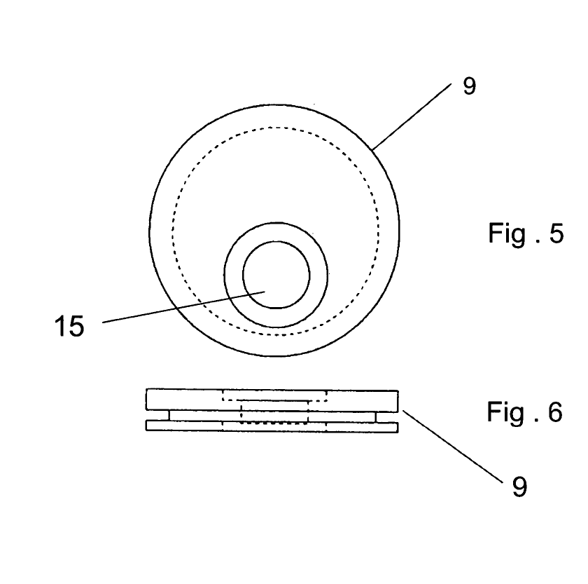

FIG. 5 is a top view of the plug connector pad with a hole to insert the input plug into the output jack of the portable handheld multimedia device.

FIG. 6 is a side view of the plug connector pad with a hole to insert the input plug into the output jack of the portable handheld multimedia device.

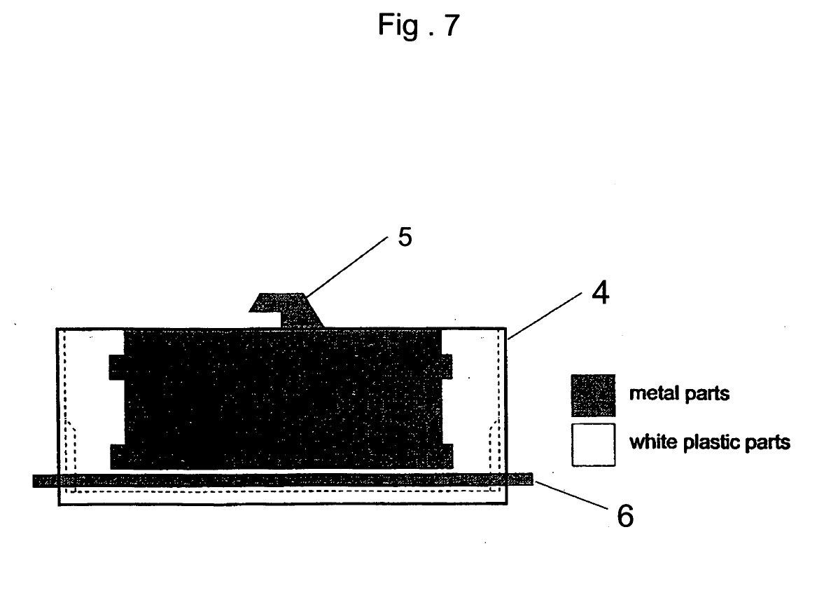

FIG. 7 is a top view of the door assembly.

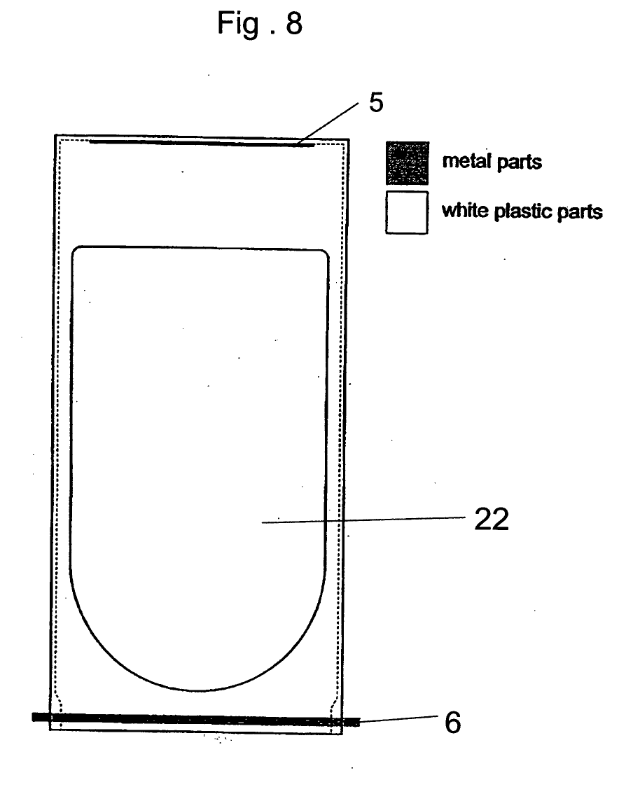

FIG. 8 is a front view of the door assembly.

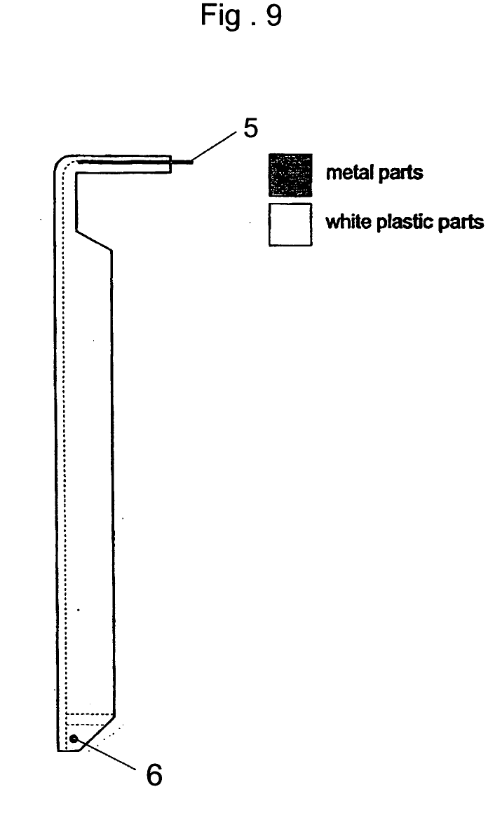

FIG. 9 is a side view of the door assembly.

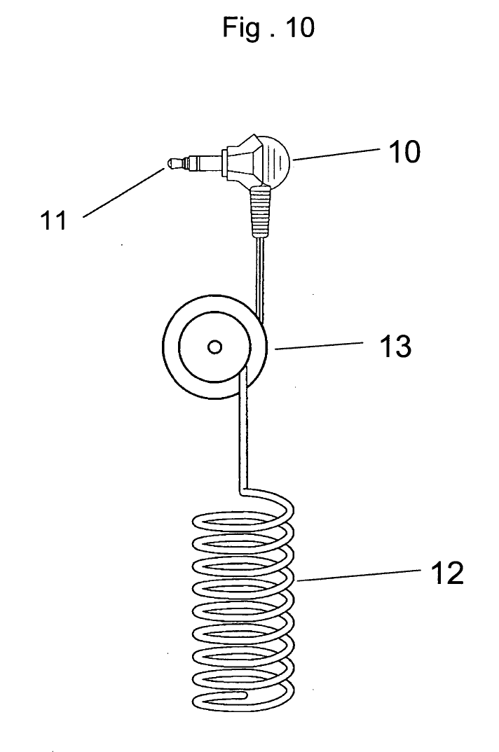

FIG. 10 is a front view of the input plug, the finger grasp, the spring mechanism, and the cable connector.

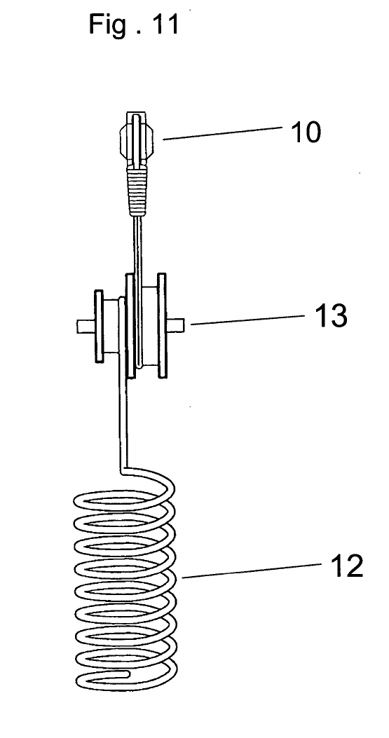

FIG. 11 is a side view of the input plug, the finger grasp, the spring mechanism, and the cable connector.

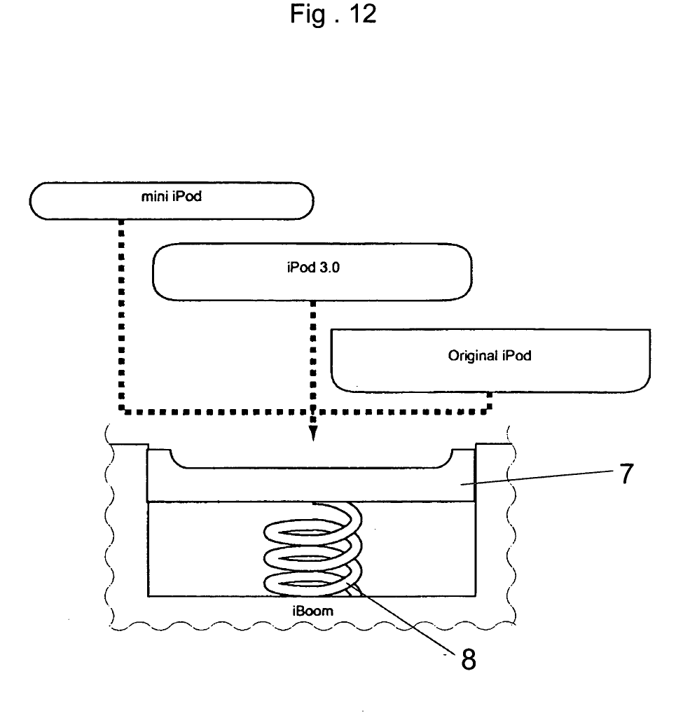

FIG. 12 is a top view of the lock plate assembly designed to accommodate in the receptacle an IPOD™3.0, an IPOD™ mini or any other portable handheld multimedia device that is smaller than the original IPOD™.

FIG. 13 is a slanted front view of the action of moving the plug aside prior to sliding in the portable handheld multimedia device.

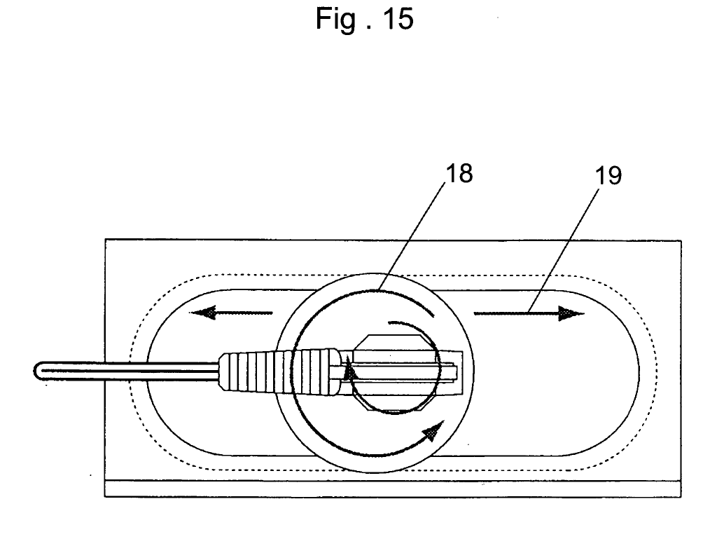

FIG. 14 is a front view of the action inserting the original IPOD™, an IPOD™ 2.0 or any other portable handheld multimedia device of a similar size while pushing back the lock plate assembly.

FIG. 15 is a top view of the action rotating and moving the input plug and the finger grasp nestled in the plug connector pad to ensure a tight fit of the portable handheld multimedia device.

FIG. 16 is a front view of the action of inserting the input plug into an “audio out” or “headphone” jack of the portable handheld multimedia device and closing the door.

FIG. 17 is a slanted front view of the lock plate assembly “cupping” and stabilizing portable handheld multimedia devices of various sizes, including IPOD™, IPOD™ 3.0, and IPOD™ mini models.

FIG. 18 is a front view of the portable audio amplifying apparatus with the portable handheld multimedia device placed inside the receptacle.

### DETAILED DESCRIPTION OF THE INVENTION

The invention described herein pertains to a portable audio amplifying apparatus for portable handheld multimedia asset player devices.

This invention provides a portable audio amplifying apparatus comprising: a receptacle for receiving a portable handheld multimedia device; a connecting means for connecting the portable handheld multimedia device to the receptacle; an amplifier means for amplifying a plurality of audio signals from the portable handheld multimedia device; at least one audio speaker 1 for delivering quality audio generated by the amplifier means; a power source means for supplying electricity to the amplifying means and the audio speakers 1; and a handle 2 on the top of the apparatus to enhance portability.

In an embodiment, the portable handheld multimedia device is a high-capacity MP3 player, including IPOD™, IPOD™ 2.0, IPOD™ 3.0 and IPOD™ mini models, or any other suitable portable handheld multimedia asset player device for recording, organizing, transmitting, manipulating, and reviewing audio files.

In this invention, the portable handheld multimedia device, such as an IPOD™ or any other MP3 player, is placed in a receptacle of the portable audio amplifying apparatus. FIG. 2 shows a slanted front view of the components of the receptacle. As shown in FIG. 2, the front door 4 of the receptacle opens to receive a portable handheld multimedia device, and a door assembly and a lock plate assembly are operatively linked the receptacle.

The operation of this portable amplifier is as follows: Pressing a button on top of the amplifier opens the door 4 and the input plug 11 nestled in the space 13 carved in along the side wall of the receptacle is pushed aside before inserting an MP3 player like IPOD™ or any other portable handheld multimedia device. In an embodiment the input plug 11 is a 3.5 mm stereo input plug.

FIG. 8 illustrates a front view of the components of the door assembly. As shown in FIG. 8, the “L”-shaped door 4 is constructed of molded plastic and contains a large opening 22 to enable the listener to access the display and control buttons of the portable handheld multimedia device. As shown, the “L”-shaped brace 5 of the door 4 is constructed of durable metal or other suitable material to prevent the door 4 from accidentally opening and the player from accidentally falling out of the receptacle. As shown in FIG. 8, the axle 6 of the door 4 is constructed of durable metal or other suitable material to further prevent the door 4 from accidentally opening, and located in the door 4 hinge to secure the portable handheld multimedia device from accidentally falling out of the front compartment. Furthermore, rubber sheet foam cut in strips and with fabric lining is adhered with adhesive to the plastic interior of the door 4 to gently cradle and protect the multimedia device.

FIG. 12 illustrates a top view of the lock plate assembly of the receptacle to accommodate MP3 players, including IPOD™ players, or other portable handheld multimedia devices of various sizes. If it is an MP3 player or any other portable handheld multimedia device of a size similar to that of an original IPOD™ player (such as an IPOD™ 2.0), the lock plate 7 should be pushed back before the device is inserted into the receptacle (this is shown as arrow 23 in FIG. 14). If it is an MP3 player or any other portable handheld multimedia device that is smaller than the original IPOD™ (such as IPOD™ 3.0 or IPOD™ mini players), once the device is securely inserted in the front plastic portion of the lock plate 7, the spring mechanism 12 pushes the lock plate 7 forward to provide easier access to the control units of the device and to maintain a tight fit of the device (this is shown in FIG. 12). The control units of the portable handheld multimedia device can be accessed and manipulated through the opening 22 in the door 4. Furthermore, rubber sheet foam cut in strips and with fabric lining is adhered with adhesive to runners on the plate 7 to gently cradle and protect the device.

FIG. 10 illustrates a front view of the connecting means sending the audio signals from the portable handheld multimedia device to the amplifier means. Once the multimedia device is securely placed in the receptacle, the input plug 11 should be inserted into an “audio out” or “headphone” jack of the multimedia device through a hole 15 in the plug connector pad 9. As shown in FIG. 10, the input plug 11 is a standard 3.5 mm mini stereo plug. As shown, the input plug 11 is attached to the finger grasp 10 that is uniquely shaped to accommodate large fingers in the confined interior of the receptacle, and the finger grasp 10 rests on top of the lock plate assembly once the input plug 11 is inserted into an “audio out” or “headphone” jack of the multimedia device. As shown in FIG. 10, the input plug 11 is attached to the spring mechanism 12 through the cable connector 13 to secure the input plug 11 in place.

FIG. 4 illustrates a front view of the finger grasp 10 and the input plug 11 nestled in the mount of the receptacle. As shown in FIG. 4, once the multimedia device is inserted, the input plug 11 and the finger grasp 10 should be rotated and moved laterally in any direction within the top frame of the lock plate assembly. The circular and lateral movements of the input plug 11 and the finger grasp 10 are shown as arrows 18 and 19, respectively, in FIG. 15. All the pieces of the plug connector pad 9 on top of the lock plate 7 is constructed of “snug” cast rubber to allow the input plug 11 and the finger grasp 10 to move laterally in any direction and the user to set the best position of the plug 11 for desired tight fit once and not have to set it again later.

Once the input plug 11 is adjusted, the door 4 should be closed, which would create lateral tension to stabilize the lock plate 7 and the input plug 11 embedded in the multimedia device. Thus, closing the door 4 locks the plate 7 into place and prevents the multimedia device, regardless its size, from moving around.

FIG. 18 illustrates a front view showing the portable audio amplifying apparatus with the portable handheld multimedia device inserted into the receptacle. As shown in FIG. 18, the audio speakers 1 to deliver audio generated by the amplifier means are OEM or after-market audio speakers. As shown, a handle 2 is placed on top to enhance portability.

The amplifier means of this invention comprises an input cable and an audio signal sensor. The input cable runs into a signal sensor and automatically switches on the amplifier. Once the signal sensor sends audio signals, the amplifier then sends the amplified signals to the audio speakers 1. As used herein, amplifier means include but is not limited to an amplifier comprising an input terminal connected to a source of electrical signals and an output terminal connected to a load, power output means.

In one embodiment, this invention uses an AC power source via a DC adaptor. In another embodiment, this invention uses a power source means of a plurality of batteries that may be rechargeable. In yet another embodiment, this invention uses a rechargeable battery module as a power source means.

As will be apparent to those skilled in the art in light of the foregoing disclosures, many alterations and modifications are possible in the practice of this invention without departing from the spirit or scope thereof. Accordingly, the scope of the invention is to be construed in accordance with the substance defined by the following claims.

What is claimed is:

1. A portable audio amplifying apparatus comprising:
a receptacle for receiving a portable handheld multimedia device;
a connecting means for connecting the portable handheld multimedia device to the receptacle;
an amplifier means for amplifying a plurality of audio signals from the portable handheld multimedia device;
at least one audio speaker for delivering quality audio generated by the amplifier means;
a power source means for supplying electricity to the amplifying means and the audio speakers; and
a handle on the top of the apparatus to enhance portability.

2. The apparatus of claim 1, wherein the portable handheld multimedia device is an MP3 player (such as IPOD™, an IPOD™ 2.0, an IPOD™ 3.0 and IPOD™ mini players) or any other suitable portable handheld multimedia asset player for recording, organizing, transmitting, manipulating, and reviewing audio files.

3. The apparatus of claim 1, wherein the audio speakers are OEM or after-market audio speakers.

4. The apparatus of claim 1, wherein the receptacle comprises a door assembly and a lock plate assembly operatively linked to the receptacle.

5. The receptacle of claim 1 as set forth in FIG. 2.

6. The apparatus of claim 4, wherein the door assembly comprises a door, a brace, and an axle.

7. The door assembly of claim 1 as set forth in FIG. 9.

8. The apparatus of claim 6, wherein the door is “L”-shaped.

9. The apparatus of claim 6, wherein the door is constructed of high-quality ABS injection molded plastic to protect the portable handheld multimedia device from the elements.

10. The apparatus of claim 6, wherein the door contains an opening to enable the listener to access the display and control buttons of the portable handheld multimedia device.

11. The apparatus of claim 6, wherein the opening in the door is a shaped hole cut in the shell of the door.

12. The apparatus of claim 6, wherein rubber sheet foam cut in strips and with fabric lining is adhered with adhesive to the plastic interior of the door to gently cradle and protect the portable handheld multimedia device from scratches.

13. The apparatus of claim 6, wherein the door is large enough to release the portable handheld multimedia device up and out of the front compartment.

14. The apparatus of claim 6, wherein the brace is “L”-shaped.

15. The apparatus of claim 6, wherein the brace is constructed of durable metal, such as stainless steel, or other suitable material to maintain the overall longevity of the door.

16. The apparatus of claim 6, wherein the brace is designed to prevent the door from accidentally opening when the door is closed, thus preventing the portable handheld multimedia device from accidentally falling out of the front compartment.

17. The apparatus of claim 6, wherein the axle is located in the door hinge to further prevent the door from accidentally opening, thus securing the portable handheld multimedia device from accidentally falling out of the front compartment.

18. The apparatus of claim 6, wherein the axle is constructed of durable metal, such as stainless steel, or other suitable material to maintain the overall longevity of the door.

19. The apparatus of claim 4, wherein a narrow space is carved in along one side of the wall to receive the connecting means.

20. The apparatus of claim 4, wherein the lock plate assembly comprises a plate, a spring mechanism and a plug connector pad on top of the plate.

21. A lock plate assembly of claim 1 as set forth in FIG. 12.

22. The apparatus of claim 20, wherein the lock plate assembly is placed between the door and the back wall of the receptacle.

23. The apparatus of claim 20, wherein the plate is constructed of high-quality ABS injection molded plastic to protect the portable handheld multimedia device from the elements.

24. The apparatus of claim 20, wherein the sides of the front plate are slightly raised to “cup” the portable handheld multimedia device and prevent it from accidentally falling out of the receptacle.

25. The apparatus of claim 20, wherein rubber sheet foam cut in strips and with fabric lining is adhered with adhesive to runners on the surface of the front plastic plate to gently cradle and protect the portable handheld multimedia device from scratches.

26. The apparatus of claim 20, wherein the spring mechanism is attached to the rear of the plate.

27. The apparatus of claim 20, wherein the spring mechanism is designed to push the plate forward to maintain the tight fit of an MP3 player or any other portable handheld multimedia device that is smaller than the original IPOD™ (such as IPOD™ 3.0 and IPOD™ mini players).

28. The apparatus of claim 20, wherein all the pieces of the plug connector pad on top the lock plate is constructed of “snug” cast rubber to allow the user to rotate and move the plug laterally in any direction to set its position once for desired tight fit and not have to set it again later.

29. The apparatus of claim 1, wherein the connecting means comprises an input plug, a finger grasp, a spring mechanism, and a cable connector.

30. A connecting means of claim 1 as set forth in FIG. 10.

31. The apparatus of claim 29, wherein the connecting means is nestled in the space in the sidewall of the receptacle.

32. The apparatus of claim 29, wherein the input plug is a standard 3.5 mm mini stereo plug.

33. The apparatus of claim 29, wherein the input plug is attached to the finger grasp.

34. The apparatus of claim 29, wherein the finger grasp is used to place the input plug into the “audio out” or “headphone” jack of the portable handheld multimedia device.

35. The apparatus of claim 29, wherein a finger grasp for the input plug is uniquely shaped to accommodate large fingers in the small space of the interior of the receptacle.

36. The apparatus of claim 29, wherein the input plug is attached to cable connector.

37. The apparatus of claim 29, wherein the cable connector is placed between the finger grasp and the spring mechanism to secure the input plug in place.

38. The apparatus of claim 1, wherein the amplifier means comprises an input cable and an audio signal sensor.

39. The apparatus of claim 38, wherein the input cable runs into a signal sensor and automatically switches on the amplifier.

40. The apparatus of claim 38, wherein the signal sensor sends audio signals to the amplifier, which then sends the amplified signals to the audio speakers.

41. The apparatus of claim 1, wherein the power source means is located in the rear compartment of the portable audio amplifying apparatus.

42. The apparatus of claim 1, wherein electricity is supplied to the power source means by an AC power source via an AC to DC converter.

43. The apparatus of claim 1, wherein electricity is supplied to the power source means by a plurality of batteries.

44. The apparatus of claim 1, wherein electricity is supplied to the power source means by a battery module.

45. The apparatus of claim 43, wherein the batteries are rechargeable batteries.

46. The apparatus of claim 1 with the portable handheld multimedia device inserted into the receptacle is as set forth in FIG. 18.

47. A method for operating the portable audio amplifying apparatus as recited in claim 1 comprising steps of:
a) Inserting four AA batteries into a power source means for receiving batteries in the rear compartment of the apparatus;
b) Pressing a button on top of the apparatus to open the door;
c) Grabbing an input plug using a finger grasp and pulling the connecting means aside as set forth in FIG. 13;
d) Sliding the portable handheld multimedia device into the receptacle as set forth in FIGS. 14;
e) Once the portable handheld multimedia device is in place, placing the input plug using the finger grasp into the “audio out” or “headphone” jack as set forth in FIG. 16;
f) Closing the door until the “L”-shaped brace of the door assembly clicks and locks in;
g) Once the door is closed, adjusting placement of the input plug to ensure the portable handheld multimedia device fit the lock plate assembly as set forth in FIG. 15;
g) Adjusting the audio output by adjusting buttons and wheel controls of the portable handheld multimedia device through the door of the receptacle;
h) Sliding the handle in the back of the unit straight up for portability of the amplifier; and
i) Pressing the button on the top of the amplifier to release the door and remove the portable handheld multimedia device.
